(19) United States
(12) Patent Application Publication
(10) Pub. No.: US 2007/0023873 A1
(43) Pub. Date: Feb. 1, 2007

(54) Package structure having recession portion on the surface thereof and method of making the same

(76) Inventors: Sang Bae Park, Kaoshiung (TW); Yong Gil Lee, Kaoshiung (TW); Jin Young Hong, Kaoshiung (TW); Bae Doo Kim, Kaoshiung (TW); Song Woon Kim, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/474,382

(22) Filed: Jun. 26, 2006

(30) Foreign Application Priority Data
Aug. 1, 2005 (TW) 094126073

(51) Int. Cl. H01L 23/495

(52) U.S. Cl. 257/666

(57) ABSTRACT

The present invention relates to a method for making a package structure having recession portion on the surface thereof. The method comprises: (a) providing a lead frame having a plurality of package units, each package unit having a plurality of leads and a die paddle; (b) providing an upper mold and a lower mold for clamping the lead frame, wherein the upper mold and the protruding block of the lower mold clamp the first portions of the leads so as to prevent molding compound bleeding to the upper surfaces of the first portions during mold filling operation, for improving the product yield; (c) injecting a molding compound between the upper mold and the lower mold, and forming a plurality of accommodation spaces; (d) attaching a plurality of chips onto the die paddles; (e) electrically connecting the chips to the first portions of the leads; (f) sealing the accommodation spaces; and (g) segregating the package units.

### BACKGROUND OF THE INVENTION

1. Field of the Invention

The present invention relates to a package structure and fabricating method thereof, and more particularly to a package structure having at least one recession portion on the lower surface and a method of making the same.

2. Description of the Related Art

Referring to FIGS. 1 to 4, the schematic sectional views of the method for making a quad flat no-lead package (QFN) with an opening are illustrated. First, referring to FIG. 1, a lead frame 10 is provided. The lead frame 10 includes a plurality of package units 11, but only one single package unit 11 is illustrated hereinafter. The package unit 11 is comprises a plurality of leads 12 and a die paddle 13, wherein the leads 12 surround the die paddle 13, and the die paddle 13 has an upper surface 131 and a lower surface 132. Each lead 12 has a first portion 121 and a second portion 122, wherein the first portion 121 has an upper surface 1211 and a lower surface 1212, and the second portion 122 has an upper surface 1221 and a lower surface 1222. The upper surfaces 1211, 1221 constitute the upper surface of the lead 12, and the lower surfaces 1212, 1222 constitute the lower surface of the lead 12, wherein the upper surface 1211 of the first portion 121 is used for wire bonding. The first portion 121 is thinner than the second portion 122, so as to form a step-like appearance.

Then, referring to FIG. 2, an upper mold 21 and a lower mold 22 are provided for clamping the lead frame 10. The upper mold 21 presses against the upper surfaces 1211 of the first portions 121 of the leads 12 and the upper surface 131 of the die paddle 13. The lower mold 22 presses against the lower surfaces 1222 of the second portions 122 of the leads 12 and the lower surface 132 of the die paddle 13. The upper mold 21 has a cavity 211.

Next, a molding compound is injected between the upper mold 21 and the lower mold 22, to form a surrounding wall portion 23 and a lower cover portion 24.

Then, referring to FIG. 3, the upper mold 21 and the lower mold 22 are removed. The surrounding wall portion 23 is disposed on the upper surface 1211 of the first portion 121 of the lead 12, and exposes the upper surface 131 of the die paddle 13 and the upper surface 1211 of the first portion 121 of the lead 12. The die paddle 13 and the surrounding wall portion 23 form an accommodation space 14. The lower cover portion 24 is disposed on the lower surface 1212 of the first portion 121 of the lead 12.

Afterwards, a chip 15 is provided. The chip 15 has an active surface 151 and a back surface 152. The back surface 152 of the chip 15 is attached to the upper surface 131 of the die paddle 13 in the accommodation space 14 by using an adhesive layer 16.

Then, a plurality of wires 17 are used to electrically connect the active surface 151 of the chip 15 to the upper surface 1211 of the first portion 121 of the lead 12.

Referring to FIG. 4, a top cover 18 is provided for covering the surrounding wall portions 23 so as to seal the accommodation space 14. If the chip 15 is an optical element, the top cover 18 is usually made of a transparent glass material. Finally, the lead frame 10 is partitioned to segregate the package units 11 thereon, i.e., to obtain a plurality of QFN packages 20.

The disadvantage of the conventional fabricating method is described as follows. The first portion 121 of the lead 12 is thinner than the second portion 122, so after the upper mold 21 and the lower mold 22 clamp the lead frame 10 in FIG. 2, the first portion 121 becomes a free end. Therefore, after the molding compound is injected, a part of the molding compound enters the upper surface 1211 of the first portion 121 and the lower surface of the upper mold 21, thus causing bleeding. As such, during continuous wire bonding operation, the wires 17 cannot be effectively connected to the upper surface 1211 of the first portion 121, thereby causing a failure or product defect.

Consequently, there is an existing need for a package structure and a package method to solve the above-mentioned problems.

### SUMMARY OF THE INVENTION

The objective of the present invention is to provide a package method, wherein a protruding block is added to the lower mold, and the upper mold and the protruding block respectively clamp the upper and lower surfaces of the first portion of the lead, thus preventing the molding compound from bleeding to the upper surface of the first portion, thereby improving the product yield.

Another objective of the present invention is to provide a package method, including the following steps:

(a) providing a lead frame, the lead frame having a plurality of package units, each package unit having a plurality of leads and a die paddle, wherein the leads surround the die paddle, each of the leads has an upper surface and a lower surface, and the die paddle has an upper surface and a lower surface;

(b) providing an upper mold and a lower mold, for clamping the lead frame, wherein the upper mold presses against the upper surfaces of the leads and the upper surfaces of the die paddles, and the lower mold has at least one protruding block pressing against the lower surfaces of the leads;

(c) injecting a molding compound between the upper mold and the lower mold, for forming a plurality of surrounding wall portions and a plurality of lower cover portions, wherein the surrounding wall portions are disposed on the upper surfaces of the leads and expose the upper surfaces of the die paddles and part of the upper surfaces of the leads, each die paddle and each surrounding wall portion form an accommodation space, and the lower cover portions are disposed on the lower surfaces of the leads;

(d) attaching a plurality of chips on the die paddles in the accommodation spaces;

(e) electrically connecting the chips to the upper surface of the leads;

(f) sealing the accommodation spaces; and

(g) segregating the package units.

Yet another objective of the present invention is to provide a package structure having a recession portion on the surface. The package structure includes a lead frame, a molding compound, a chip, and a top cover. The lead frame has a plurality of leads and a die paddle. The leads surround the die paddle, and each of the leads has a first portion with an upper surface and a lower surface. The die paddle has an upper surface and a lower surface.

The molding compound includes a surrounding wall portion and a lower cover portion. The surrounding wall portion is disposed on the upper surface of the first portion, and exposes the upper surface of the die paddle and the upper surface of the first portion. The die paddle and the surrounding wall portion form an accommodation space. The lower cover portion is disposed on the lower surface of the first portion, and has at least one recession portion exposing a part of the lower surface of the first portion. The chip is disposed on the die paddle in the accommodation space, and is electrically connected to the upper surface of the first portion via a plurality of wires. The top cover is disposed above the chip for sealing the accommodation space.

### BRIEF DESCRIPTION OF THE DRAWINGS

FIGS. 1 to 4 show the schematic sectional views of the method for making a conventional QFN package with an opening;

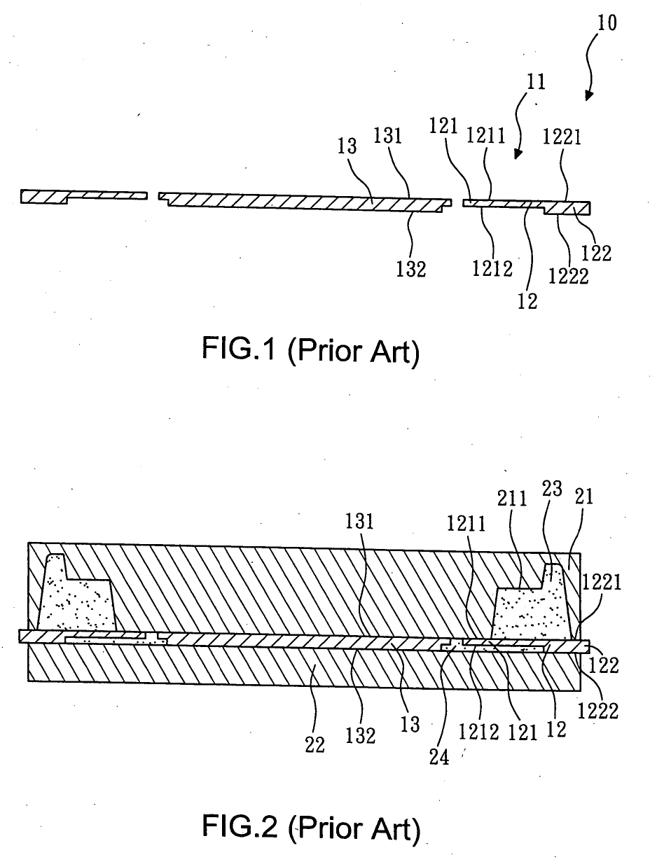

FIGS. 5 to 11 show the schematic views of the method for making a package structure having a recession portion on the surface according to the first embodiment of the present invention;

FIG. 12 shows the schematic cross-sectional view of the package structure according to the second embodiment of the present invention;

FIG. 13 shows the bottom schematic perspective view of the package unit according to the second embodiment of the present invention;

FIG. 14 shows the schematic cross-sectional view of the package structure according to the third embodiment of the present invention;

FIGS. 15 to 18 show the schematic cross-sectional views of the method for making the package structure according to the third embodiment of the present invention;

FIG. 19 shows the schematic cross-sectional view of the package structure according to the fourth embodiment of the present invention;

FIG. 20 shows the schematic cross-sectional view of the package structure according to the fifth embodiment of the invention;

FIG. 21 shows the schematic cross-sectional view of the package structure according to the sixth embodiment of the invention;

FIG. 22 shows the schematic cross-sectional view of the package structure according to the seventh embodiment of the invention;

FIG. 23 shows the schematic cross-sectional view of the package structure according to the eighth embodiment of the invention; and

FIG. 24 shows the schematic cross-sectional view of the package structure according to the ninth embodiment of the invention.

### DETAILED DESCRIPTION OF THE INVENTION

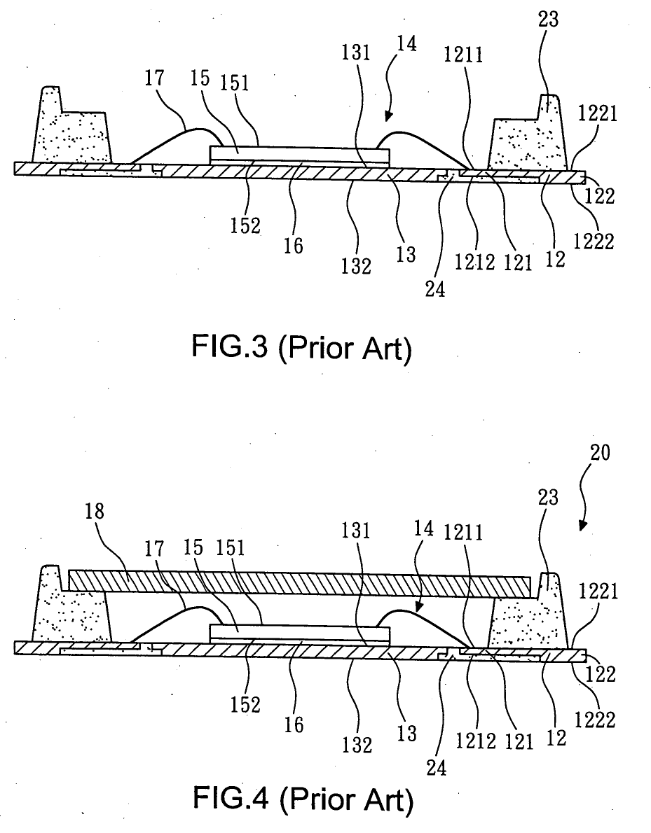

Referring to FIGS. 5 to 11, the schematic sectional views of the method for making a package structure having a recession portion on the surface according to the first embodiment of the present invention are illustrated. First, referring to FIG. 5, a lead frame 30 is provided. The lead frame 30 includes a plurality of package units 31, but only one package unit 31 is illustrated hereinafter. The package unit 31 has a plurality of leads 32 and a die paddle 33, with the leads 32 surrounding the die paddle 33. The die paddle 33 has an upper surface 331 and a lower surface 332. In the embodiment, the upper surface 331 of the die paddle 33 has a plurality of ribs (not shown), for increasing the force for holding the chip. Each lead 32 has a first portion 321 and a second portion 322. The first portion 321 has an upper surface 3211 and a lower surface 3212, and the second portion 322 has an upper surface 3221 and a lower surface 3222. The upper surfaces 3211, 3221 constitute the upper surface of the lead 32, and the lower surfaces 3212, 3222 constitute the lower surface of the lead 32. The upper surface 3211 of the first portion 321 is used for wire bonding. The first portion 321 is thinner than the second portion 322, so as to form a step-like appearance.

Afterward, referring to FIG. 6, an upper mold 41 and a lower mold 42 are provided for clamping the lead frame 30. The upper mold 41 presses against the upper surface 3211 of the first portion 321 of the lead 32 and the upper surface 331 of the die paddle 33. The upper mold 41 has a cavity 411. In the embodiment, the upper mold 41 further includes at least one pin 412 extending into the cavity 411.

The lower mold 42 presses against the lower surface 3222 of the second portion 322 of the lead 32 and the lower surface 332 of the die paddle 33. Moreover, the lower mold 42 further includes at least one protruding block 421 pressing against the lower surface 3212 of the first portion 321 of the lead 32. By using the protruding block 421 and the upper mold 41 to clamp the first portion 321 of the lead 32, the molding compound can be prevented from bleeding to the upper surface 3211 of the first portion 321 during continuous mold filling operation.

Then, a molding compound is injected between the upper mold 41 and the lower mold 42, for forming a surrounding wall portion 43 and a lower cover portion 44.

Then, referring to FIG. 7, the upper mold 41 and the lower mold 42 are removed. The surrounding wall portion 43 is disposed on the upper surface 3211 of the first portion 321 of the lead 32, and exposes the upper surface 331 of the die paddle 33 and part of the upper surface 3211 of the first portion 321 of the lead 32. The die paddle 33 and the surrounding wall portion 43 form an accommodation space 34. The surrounding wall portion 43 has at least one hole 431 formed by the pin 412. The lower cover portion 44 is disposed on the lower surface 3212 of the first portion 321 of the lead 32, and has at least one recession portion 441. The recession portion 441 is formed by the protruding block 421, and exposes a part of the lower surface 3212 of the first portion 321. The top and the bottom schematic stereograms of the package unit 31 are shown respectively in FIG. 8 and FIG. 9.

After that, a chip 35 is provided. The chip 35 has an active surface 351 and a back surface 352. The back surface 352 of the chip 35 is attached to the upper surface 331 of the die paddle 33 in the accommodation space 34 via an adhesive layer 36.

Then, a plurality of wires 37 are used to electrically connect the active surface 351 of the chip 35 to the upper surface 3211 of the first portion 321 of the lead 32.

Then, referring to FIG. 10, a gel 45 is injected into the accommodation space 34. It should be noted that the step of injecting the gel 45 is not necessary in the invention, i.e., the gel 45 may not be injected according to the invention. Then, a top cover 38 is provided for covering the surrounding wall portion 43 so as to seal the accommodation space 34. In the embodiment, the top cover 38 has at least one through hole 381, for exhausting the compressed air inside the accommodation space 34 when the top cover 38 is put on. If the chip 35 is an optical element, the material of the top cover 38 usually can be a transparent glass material. If the chip 35 is not an optical element, the material of the top cover 38 can be ceramic, plastic, metal, or the like. In the embodiment, the gel 45 is injected at first and then the top cover 38 is put on. However, the gel 45 can also be injected via the through hole 381 after the top cover 38 is put on.

Referring to FIG. 11, the partial enlarged schematic view of the surrounding wall portion of the molding compound according to the invention is illustrated. In the invention, a plurality of cutouts 432 is disposed in the surrounding wall portion 43 for preventing the gel 45 from suddenly bleeding out of the accommodation space 34. The cutouts 432 are of a step-like appearance, for increasing the accommodation space of the gel 45. When the liquid level of the gel 45 rises gradually, the gel 45 will enter the cutouts 432 at first, instead of bleeding out of the accommodation space 34 at once.

Finally, the lead frame 30 is partitioned to segregate the package units 31 thereon, i.e., to obtain a plurality of package structures 40 according to the first embodiment.

Referring to FIG. 10 again, the schematic cross-sectional view of the package structure according to the first embodiment of the present invention is shown. The package structure 40 includes a lead frame 30, a molding compound, a chip 35, a gel 45, and a top cover 38.

The lead frame 30 has a plurality of leads 32 and a die paddle 33. The leads 32 surround the die paddle 33, and the die paddle 33 has an upper surface 331 and a lower surface 332. In the embodiment, the upper surface 331 of the die paddle 33 has a plurality of ribs (not shown), for increasing the force for holding the chip 35. Each lead 32 has a first portion 321 and a second portion 322. The first portion 321 has an upper surface 3211 and a lower surface 3212, while the second portion 322 has an upper surface 3221 and a lower surface 3222. The upper surfaces 3211, 3221 constitute the upper surface of the lead 32, and the lower surfaces 3212, 3222 constitute the lower surface of the lead 32. The upper surface 3211 of the first portion 321 is used for wire bonding. The first portion 321 is thinner than the second portion 322, so as to form a step-like appearance. The thickness of the die paddle 33 is identical to that of the second portion 322. The height of the upper surface 3211 of the first portion 321 of the lead is identical to that of the upper surface 331 of the die paddle 33. The height of the lower surface 3222 of the second portion 322 of the lead is identical to that of the lower surface 332 of the die paddle 33.

The molding compound includes a surrounding wall portion 43 and a lower cover portion 44. The surrounding wall portion 43 is disposed on the upper surface 3211 of the first portion 321, and exposes the upper surface 331 of the die paddle 33 and the upper surface 3211 of the first portion 321. The die paddle 33 and the surrounding wall portion 43 form an accommodation space 34. Preferably, the surrounding wall portion 43 has at least one hole 431 for positioning. The lower cover portion 44 is disposed on the lower surface 3212 of the first portion 321, and has at least one recession portion 441 exposing a part of the lower surface 3212 of the first portion 321.

The chip 35 has an active surface 351 and a back surface 352. The back surface 352 of the chip 35 is attached to the upper surface 331 of the die paddle 33 in the accommodation space 34 via an adhesive layer 36, and a plurality of wires 37 is used for electrically connecting the active surface 351 of the chip 35 to the upper surface 3211 of the first portion 321.

The gel 45 is disposed in the accommodation space 34, for preventing the wires 37 from contacting each other and being oxidized. The gel 45 can just be coated on the active surface 351 of the chip 35 or injected in the accommodation space 34. Preferably, the surrounding wall portion 43 is provided with a plurality of cutouts 432 (as shown in FIG. 11) for preventing the gel 45 from suddenly bleeding out of the accommodation space 34.

The top cover 38 is disposed above the chip 35, for sealing the accommodation space 34. If the chip 35 is an optical element, the material of the top cover 38 usually can be a transparent glass material. If the chip 35 is not an optical element, the material of the top cover 38 can be ceramic, plastic, metal, or the like. In the embodiment, the top cover 38 has at least one through hole 381, for exhausting the compressed air inside the accommodation space 34 when the top cover 38 is put on, or for injecting the gel 45.

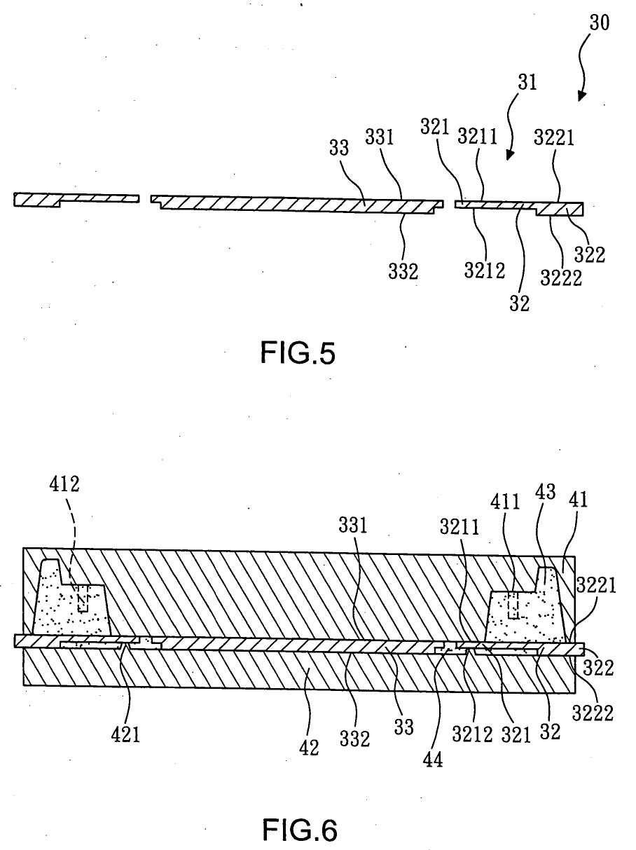

Referring to FIG. 12, a schematic cross-sectional view of the package structure according to the second embodiment of the present invention is shown. The package structure 40A includes a lead frame 30, a molding compound (having a surrounding wall portion 43 and a lower cover portion 44), a chip 35, a gel 45, and a top cover 38. The package structure 40A is substantially the same as the package structure 40 of the first embodiment, but the pattern of the lead frame 30 is different. In the embodiment, the thickness of the die paddle 33 is the same as that of the first portion 321 of the lead 32. The height of the upper surface 3211 of the first portion 321 of the lead 32 is identical to that of the upper surface 331 of the die paddle 33. The height of the lower surface 332 of the die paddle 33 is identical to that of the lower surface 3212 of the first portion 321 of the lead 32.

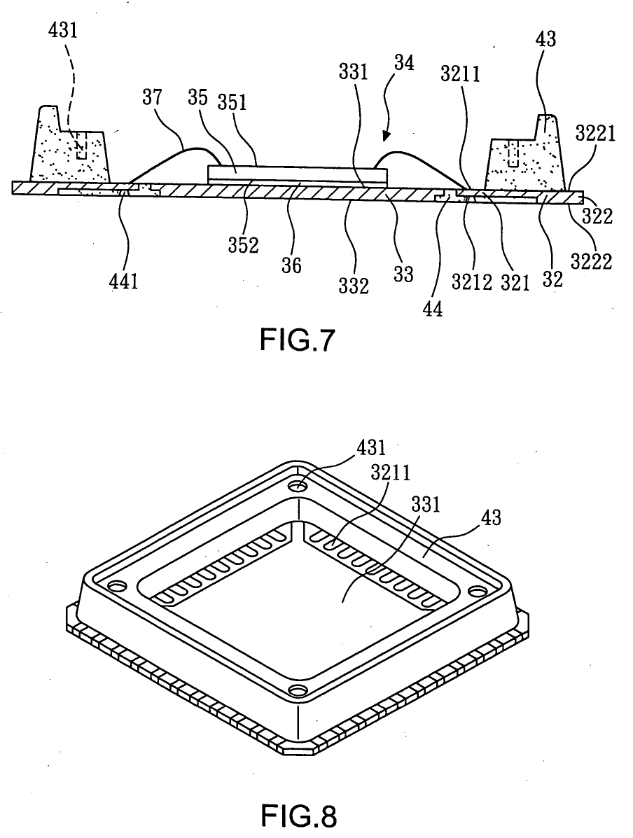

Furthermore, in the embodiment, the lower cover portion 44 covers the lower surface 332 of the die paddle 33, and the lower cover portion 44 further includes at least one hole 442 exposing a part of the lower surface 332 of the die paddle 33. The hole 442 is formed by adding a pin (not shown) to the lower mold 42. When the upper and lower molds 41, 42 clamp the lead frame 30, the pin presses against the lower surface 332 of the die paddle 33, and forms the hole 442 after the mold filling operation, as shown in FIG. 13.

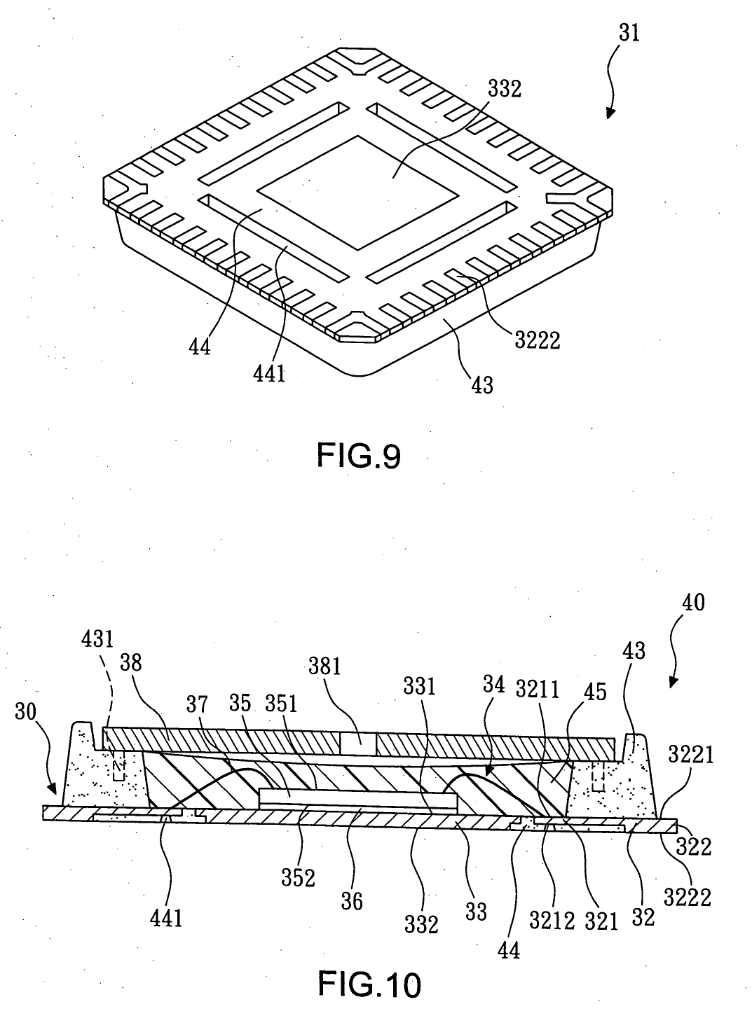

Referring to FIG. 14, a schematic sectional view of the package structure according to the third embodiment of the present invention is shown. The package structure 40B includes a lead frame 30, a molding compound (having a surrounding wall portion 43 and a lower cover portion 44), a chip 35, a gel 45, and a top cover 38. The package structure 40B is substantially the same as the package structure 40 of the first embodiment, but the pattern of the lead frame 30 is different. In the embodiment, the lead frame 30 does not have the die paddle, and the leads 32 are arranged circularly. Each of the leads 32 has a first portion 321 and a second portion 322.

The molding compound includes the surrounding wall portion 43 and the lower cover portion 44. The surrounding wall portion 43 is disposed on the upper surface 3211 of the first portion 321 of the lead 32, and exposes the upper surface 3211 of the first portion 321 of the lead 32. Preferably, the surrounding wall portion 43 also has a hole 431. The lower cover portion 44 is disposed on the lower surface 3212 of the first portion 321 of the lead 32, and has an upper surface 443 and a recession portion 441. The lower cover portion 44 and the surrounding wall portion 43 form an accommodation space 34. The recession portion 441 exposes the lower surface 3212 of the first portion 321 of the lead 32. Preferably, the lower cover portion 44 also has a hole 442.

The chip 35 is provided with an active surface 351 and a back surface 352. The back surface 352 of the chip 35 is attached to the upper surface 443 of the lower cover portion 44 in the accommodation space 34 via an adhesive layer 36, and the active surface 351 of the chip 35 is eclectically connected to the upper surface 3211 of the first portion 321 via a plurality of wires 37. The top cover 38 is disposed above the chip 35, for sealing the accommodation space 34.

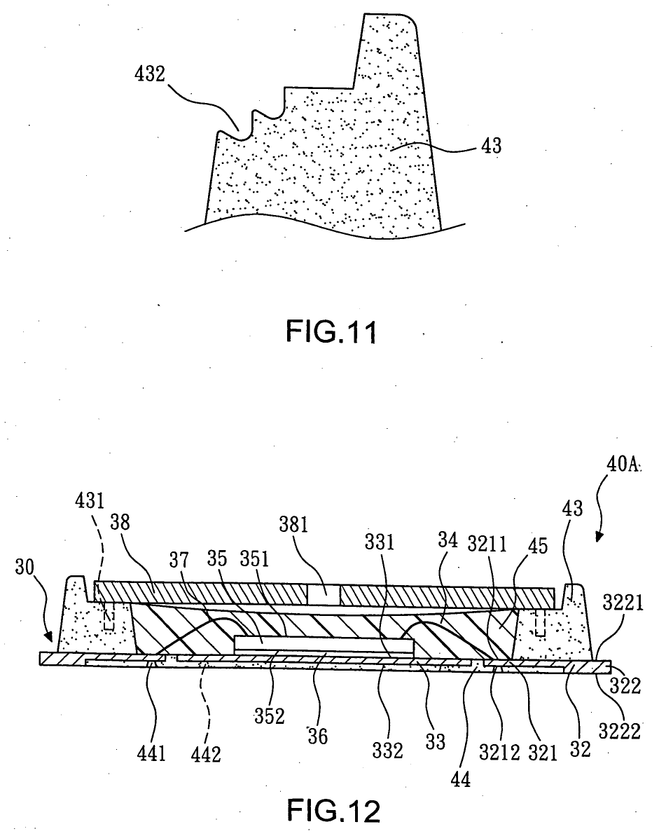

Referring to FIGS. 15 to 18, a method for fabricating the package structure according to the third embodiment of the present invention is illustrated. The fabricating method of the package structure 40B is described as follows. First, referring to FIG. 15, a lead frame 30 is provided. The lead frame 30 has a plurality of package units 31, and each package unit 31 has a plurality of leads 32 arranged circularly. Each of the leads 32 has a first portion 321 and a second portion 322. The first portion 321 has an upper surface 3211 and a lower surface 3212, and the second portion 322 has an upper surface 3221 and a lower surface 3222. The upper surfaces 3211, 3221 form the upper surface of the lead 32, and the lower surfaces 3212, 3222 form the lower surface of the lead 32, wherein the upper surface 3211 of the first portion 321 is used for wire bonding.

After that, referring to FIG. 16, an upper mold 41 and a lower mold 42 are provided for clamping the lead frame 30. The upper mold 41 presses against the upper surface 3211 of the first portion 321 of the lead 32. The lower mold 42 has at least one protruding block 421 and a pin 422. The protruding block 421 presses against the lower surface 3212 of the first portion 321 of the lead 32, and the pin 422 presses against the upper mold 41 to form the hole 442. Then, a molding compound is injected between the upper mold 41 and the lower mold 42, for forming the surrounding wall portions 43 and the lower cover portions 44. After the upper mold 41 and the lower mold 42 are removed, the surrounding wall portions 43 are disposed on the upper surfaces 3211 of the first portions 321 of the leads 32, and expose part of the upper surfaces 3211 of the first portions 321 of the leads 32. The lower cover portions 44 are disposed on the lower surfaces 3212 of the first portions 321 of the leads 32, and each of them has an upper surface 443. The lower cover portion 44 and each surrounding wall portion 43 form an accommodation space 34.

Next referring to FIG. 17, the chip 35 is attached to the upper surface 443 of the lower cover portions 44 in the accommodation space 34. Then, a plurality of wires 37 is formed to electrically connect the chip 35 to the upper surface 3212 of the first portion 321 of the lead 32.

Then, referring to FIG. 18, the top cover 38 is used to seal the accommodation space 34. Finally, the lead frame 30 is partitioned to segregate the package units 31 thereon, i.e., to obtain a plurality of package structures 40B.

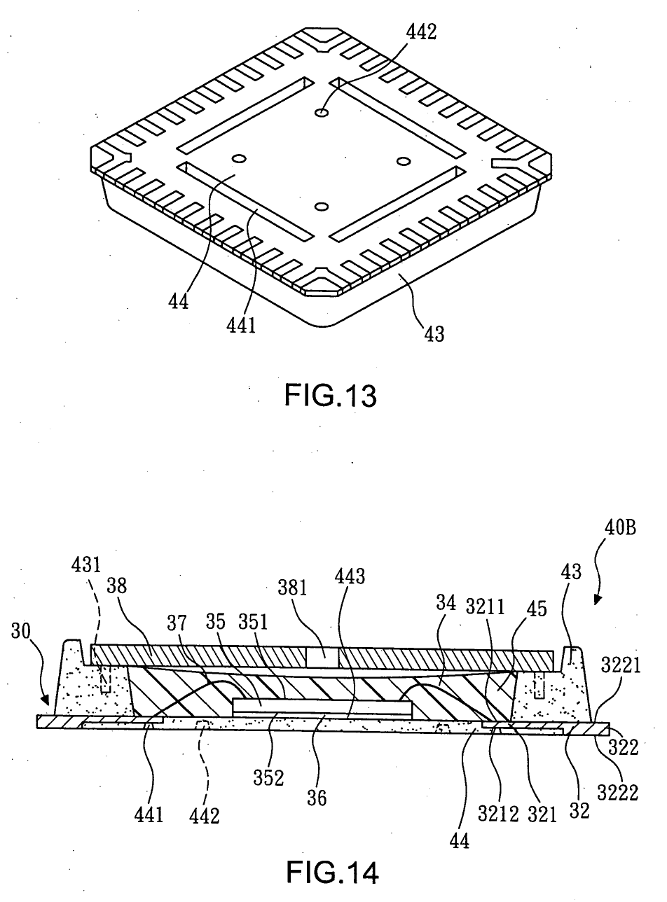

Referring to FIG. 19, a schematic cross-sectional view of the package structure according to the fourth embodiment of the present invention. The package structure 50 includes a lead frame 30, a molding compound (having a surrounding wall portion 43 and a lower cover portion 44), a chip 35, a gel 45, and a top cover 38. The package structure 50 is substantially the same as the package structure 40 of the first embodiment, but the pattern of the lead frame 30 is different. In the embodiment, the leads 32 are of a uniform thickness, while the lower surface 3212 of the first portion 321 of the lead 32 is higher than the lower surface 3222 of the second portion 322, thus forming a bent appearance. The thickness of the die paddle 33 is identical to that of the first portion 321 of the lead 32. The upper surface 331 of the die paddle 33 is of the same height as the upper surface 3211 of the first portion 321 of the lead 32.

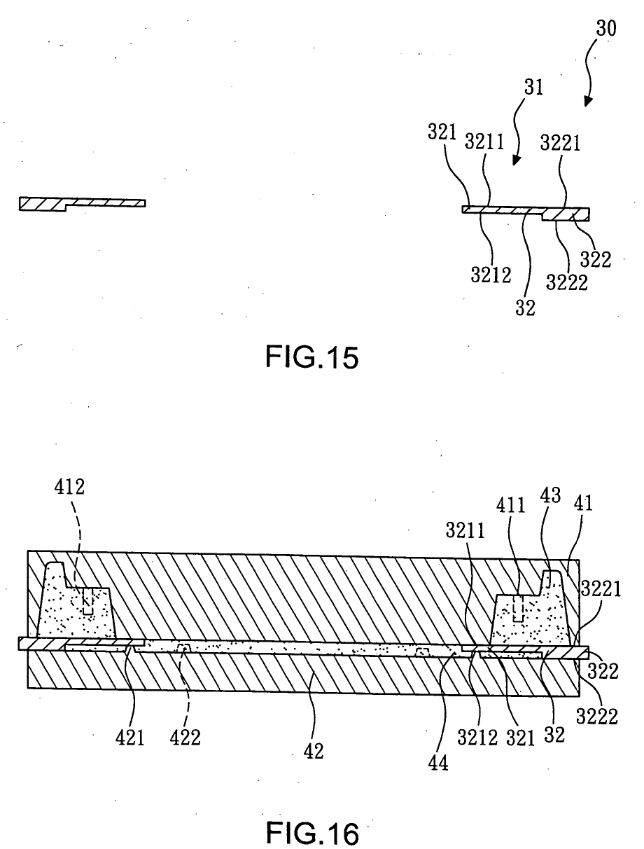

Referring to FIG. 20, a schematic sectional view of the package structure according to the fifth embodiment of the present invention is shown. The package structure 50A of the present embodiment is substantially the same as the package structure 40A of the second embodiment, but the pattern of the lead frame 30 is different. In the embodiment, the leads 32 are of a uniform thickness, and the lower surface 3212 of the first portion 321 of the lead 32 is higher than the lower surface 3222 of the second portion 322, so as to form a bent appearance. The die paddle 33 is thinner than the first portion 321 of the lead 32. The upper surface 331 of the die paddle 33 is of the same height as the upper surface 3211 of the first portion 321 of the lead 32.

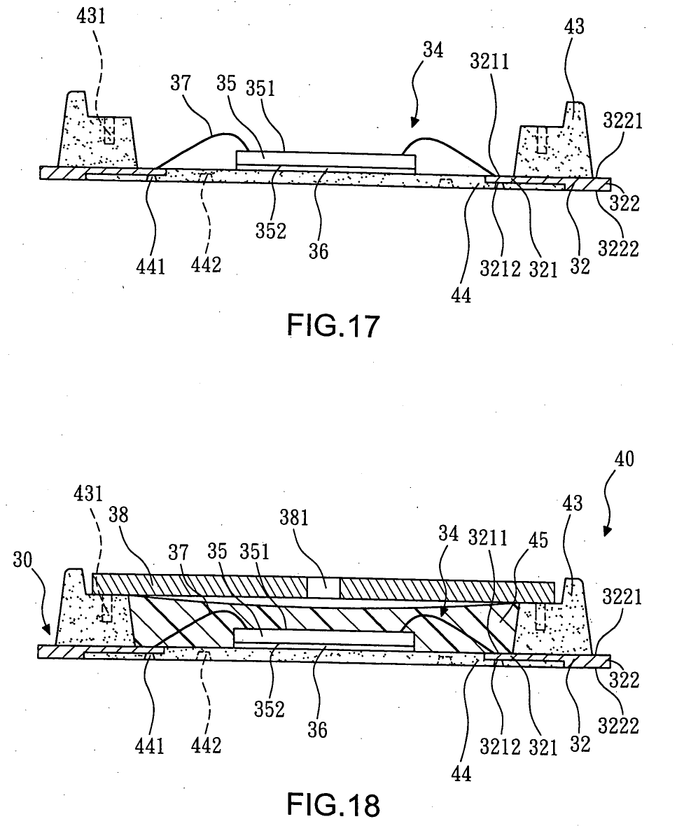

Referring to FIG. 21, a schematic cross-sectional view of the package structure according to the sixth embodiment is shown. The package structure 50B of the present embodiment is substantially the same as the package structure 40B of the third embodiment, but the pattern of the lead frame 30 is different. In the embodiment, the leads 32 are of a uniform thickness, and the lower surface 3212 of the first portion 321 of the lead 32 is higher than the lower surface 3222 of the second portion 322, so as to form a bent appearance.

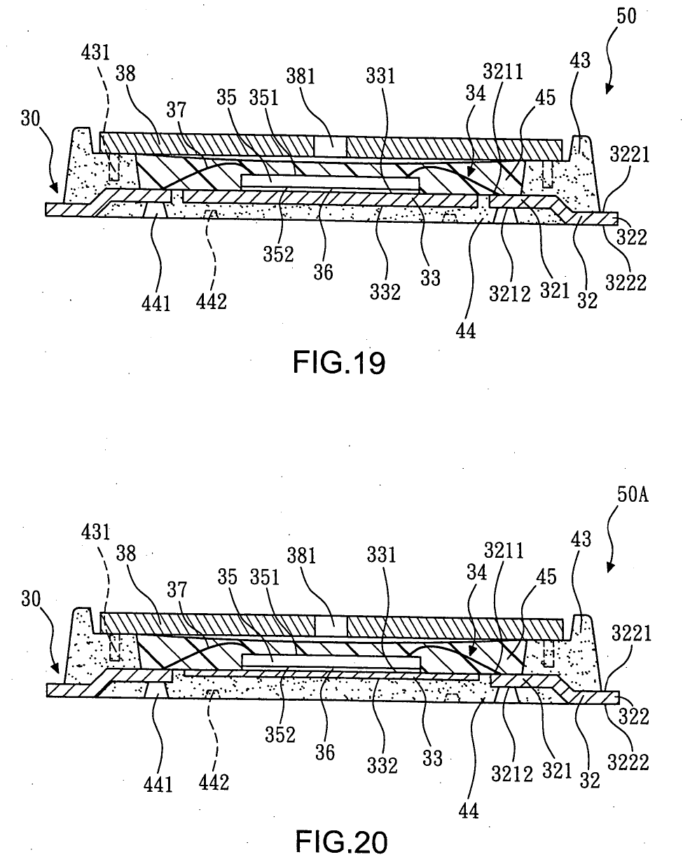

Referring to FIG. 22, a schematic cross-sectional view of the package structure according to the seventh embodiment of the present invention is shown. The package structure 60 of the embodiment is substantially the same as the package structure 50 of the fourth embodiment, but the pattern of the lead frame 30 is different. In the embodiment, the lower surface 332 of the die paddle 33 is of the same height as the lower surface 3222 of the second portion 322 of the lead 32.

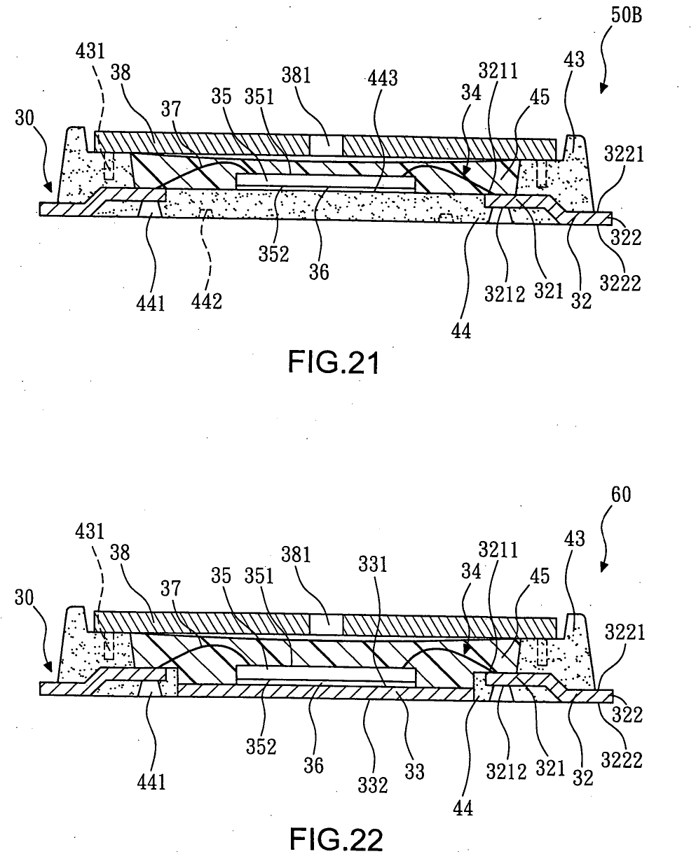

Referring to FIG. 23, a schematic cross-sectional view of the package structure according to the eighth embodiment of the present invention. The package structure 60A of the embodiment is substantially the same as the package structure 50A of the fifth embodiment, but the pattern of the lead frame 30 is different. In the embodiment, the die paddle 33 is thinner than the first portion 321 of the lead 32. The upper surface 331 of the die paddle 33 is lower than the upper surface 3211 of the first portion 321 of the lead 32. And the lower surface 332 of the die paddle 33 is higher than the lower surface 3222 of the second portion 322 of the lead 32.

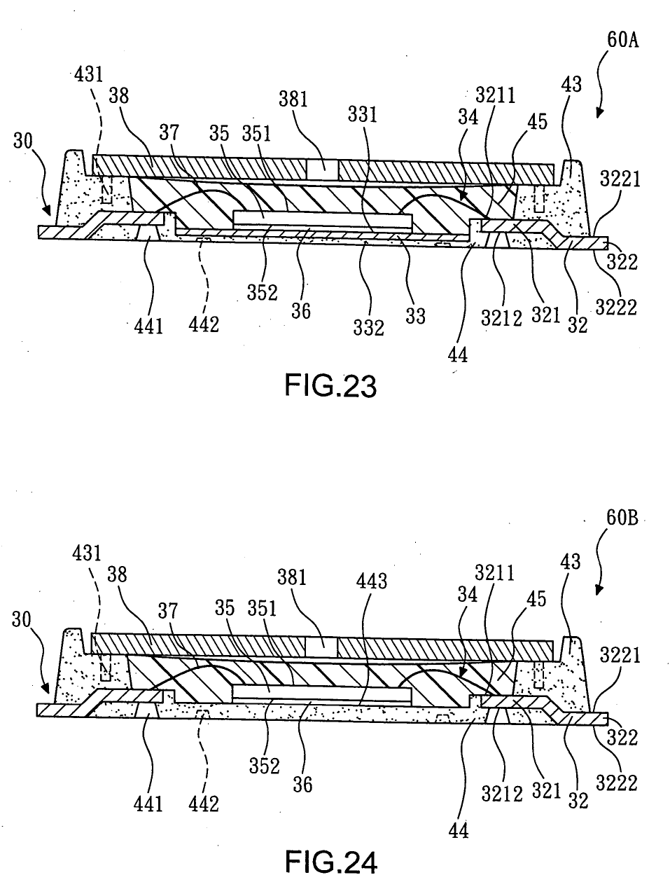

Referring to FIG. 24, a schematic cross-sectional view of the package structure according to the ninth embodiment of the present invention. The package structure 60B of the embodiment is substantially the same as the package structure 5OB of the sixth embodiment, but the pattern of the lead frame 30 is different. In the embodiment, the upper surface 443 of the lower cover portion 44 is lower than the upper surface 3211 of the first portion 321 of the lead 32.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A package structure having a recession portion on the surface, comprising:
a lead frame, having a plurality of leads and a die paddle, the leads surrounding the die paddle, each of the leads having an upper surface and a lower surface, and the die paddle having an upper surface and a lower surface;
a molding compound, having a surrounding wall portion and a lower cover portion, the surrounding wall portion being disposed on the upper surface of the lead, part of the upper surface of the die paddle and the upper surface of the lead being exposed, an accommodation space being formed by the die paddle and the surrounding wall portion, and the lower cover portion being disposed on the lower surface of the lead and having at least one recession portion exposing the lower surface of the lead;
a chip, disposed on the die paddle in the accommodation space, and electrically connected to the upper surface of the lead via a plurality of wires; and
a top cover, disposed above the chip for sealing the accommodation space.

2. The package structure according to claim 1, wherein each lead has a first portion and a second portion, the first portion is used for wire bonding and the second portion is exposed outside the molding compound, and the first portion of the lead is thinner than the second portion, so as to form a step-like appearance.

3. The package structure according to claim 1, wherein each lead has a first portion and a second portion, the first portion is used for wire bonding and has an upper surface and a lower surface, the second portion is exposed outside the molding compound and has an upper surface and a lower surface, and the lower surface of the first portion of the lead is higher than the lower surface of the second portion, so as to form a bent appearance.

4. The package structure according to claim 1, wherein the lower cover portion of the molding compound further comprises at least one hole exposing a part of the lower surface of the die paddle.

5. The package structure according to claim 1, wherein the surrounding wall portion of the molding compound further comprises at least one hole.

6. The package structure according to claim 1, further comprising a gel disposed in the accommodation space.

7. The package structure according to claim 6, wherein the surrounding wall portion of the molding compound has a plurality of cutouts, for preventing the gel from bleeding out of the accommodation space.

8. The package structure according to claim 1, wherein the top cover has at least one through hole.

9. A package structure having a recession portion on the surface, comprising:
a lead frame, having a plurality of leads arranged circularly, each of the leads having an upper surface and a lower surface;
a molding compound, having a surrounding wall portion and a lower cover portion, the surrounding wall portion being disposed on the upper surface of the leads, part of the upper surface of the leads being exposed, the lower cover portion being disposed on the lower surface of the leads and having an upper surface, the lower cover portion and the surrounding wall portion form an accommodation space, and the lower cover portion having at least one recession portion for exposing the lower surface of the leads;
a chip, disposed on the upper surface of the lower cover portion in the accommodation space, and electrically connected to the upper surface of the leads via a plurality of wires; and
a top cover, disposed above the chip, for sealing the accommodation space.

10. The package structure according to claim 9, wherein each lead has a first portion and a second portion; the first portion is used for wire bonding, and the second portion is exposed outside the molding compound; and the first portion of the lead is thinner than the second portion, so as to form a step-like appearance.

11. The package structure according to claim 9, wherein each lead has a first portion and a second portion; the first portion is used for wire bonding, and the second portion is exposed outside the molding compound; and the first portion of the lead is higher than the second portion, so as to form a bent appearance.

12. The package structure according to claim 9, wherein the lower cover portion of the molding compound further comprises at least one hole exposing the lower surface of the chip.

13. The package structure according to claim 9, wherein the surrounding wall portion of the molding compound further comprises at least one hole.

14. The package structure according to claim 9, further comprising a gel, disposed in the accommodation space.

15. The package structure according to claim 14, wherein the surrounding wall portion of the molding compound has a plurality of cutouts, for preventing the gel from bleeding out of the accommodation space.

16. The package structure according to claim 9, wherein the top cover has at least one through hole.
